(19) United States
(12) Patent Application Publication
(10) Pub. No.: US 2012/0252344 A1
(43) Pub. Date: Oct. 4, 2012

(54) HEAT-DISSIPATING DUAL-SYSTEM RACKMOUNT FOR 1U INDUSTRIAL COMPUTER

(76) Inventors: Chih-Yung Chien, Luchu Shiang (TW); Sophia Chen, Luchu Shiang (TW)

(21) Appl. No.: 13/078,050

(22) Filed: Apr. 1, 2011

(51) Int. Cl. H05K 5/02

(52) U.S. Cl. 454/184

(57) ABSTRACT

A heat-dissipating dual-system rackmount for a 1U industrial computer includes a removable rackmount and two removable computer cases. The rackmount features that two lateral plates of the removable computer case are formed with vents for heat dissipation, and that two laterals and a partition of the rackmount are formed with air channels, along which air channels air vents are formed corresponding to the vents for heat dissipation of the removable computer case, thereby improving ventilation among the heat-generating components in the removable computer case and in turn providing good heat-dissipation effects.

### BACKGROUND OF THE INVENTION

1. Technical Field

The present invention relates to a device facilitating heat dissipation of a removable dual-system rackmount for a 1U industrial computer, and more particularly, to a rackmount whose lateral plates and partition are provided with air channels for improving ventilation of removable computer cases that contain heat-generating components, thereby providing good heat-dissipation effects.

2. Description of Related Art

Commercially available industrial computers are mainly counted in highly normalized computer cases, such as 1U computers and 2U, 3U, 4U or 5U computers constructed from two or more units stacked in height.

Such an industrial computer, either a 1U or a multi-unit one, always include a removable rackmount for receiving one or more removable computer case each carrying a motherboard (M/B), a power supply, a hard drive and a heat-dissipating fan [CD-ROM driver]. Typically, heat dissipation of the industrial computer relies on a plurality of heat-dissipating fan abreast arranged in the removable computer case absorbing cold air from a front plate of the case, making the cold air pass by the M/B installed thereon a CPU, an extension holder and I/O terminals, the power supply and particularly the highly heat-generating hard drive, and expelling hot air through a back plate of the case. Air flowing this way somehow helps the components in the removable computer case to dissipate heat.

As known, the components in the removable computer case are close arranged and have different heights and shapes. According to the principle of hydromechanic suggesting fluid flowing from high-pressure sites to low-pressure sites, the foregoing one-way air flow among the components in the removable computer case is not effective in dissipating heat.

In addition, the removable rackmount typically has a large lower cover for bearing the overall weight of the removable computer case, and for the same purpose, the lower cover traditionally has to be made of a thick metal plate; otherwise it might deform due to insufficient strength.

### SUMMARY OF THE INVENTION

In view that the conventional removable dual-system rackmount for a 1U industrial computer is short of heat-dissipation capability and mechanical strength, the present invention proposed the following solution to improve heat dissipation for removable computer cases in the 1U industrial computer and enhance strength of a lower cover of the rackmount.

In order to improve heat dissipation for the removable computer case, the present invention provides schemes including formation of vents for heat dissipation at two lateral plates of the removable computer case where heat tends to appear, and formation of air channels at two laterals and a partition of the removable rackmount, along which air channels air vents are arranged corresponding to the vents for heat dissipation of the removable computer case, thereby improving ventilation among the heat-generating components in the removable computer case and in turn providing good heat-dissipation effects.

In order to enhance strength of the lower cover of the rackmount, the present invention provides a scheme of equipping the lower cover with ribs by pressing, thereby reinforcing the structure.

### BRIEF DESCRIPTION OF THE DRAWINGS

The invention as well as a preferred mode of use, further objectives and advantages thereof will be best understood by reference to the following detailed description of illustrative embodiments when read in conjunction with the accompanying drawings, wherein:

FIG. 1 is a perspective view of the present invention;

FIG. 2 is a schematic view of the present invention wherein upper covers of removable computer cases are removed;

FIG. 3 is atop view of the present invention of FIG. 2; and

FIG. 4 is a schematic drawing showing air-flow directions for heat dissipation provided by the present invention.

### DETAILED DESCRIPTION OF THE INVENTION

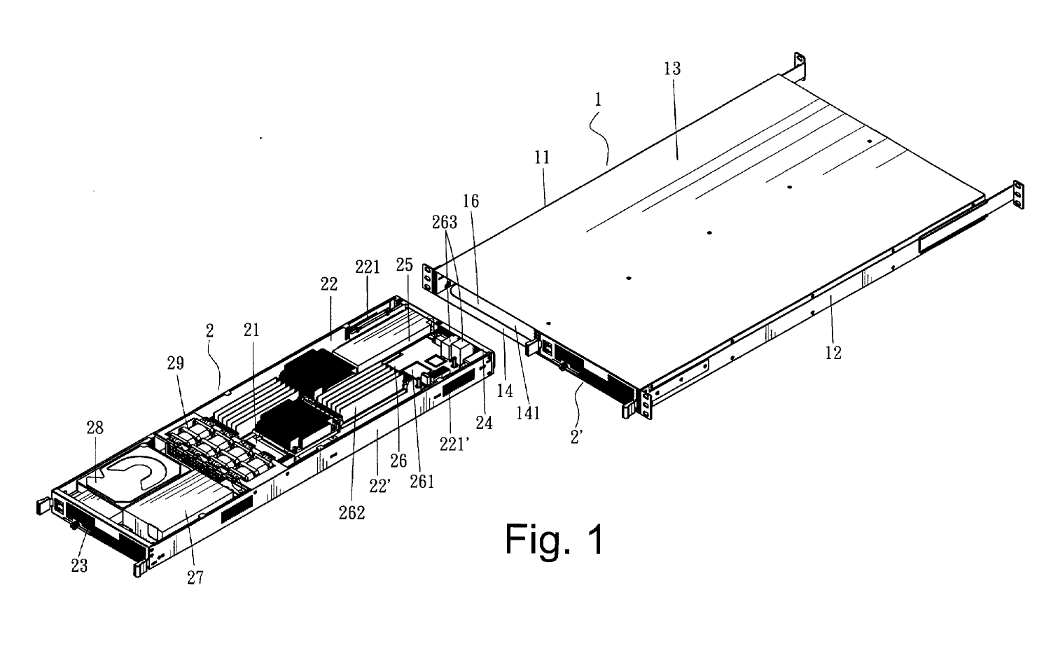

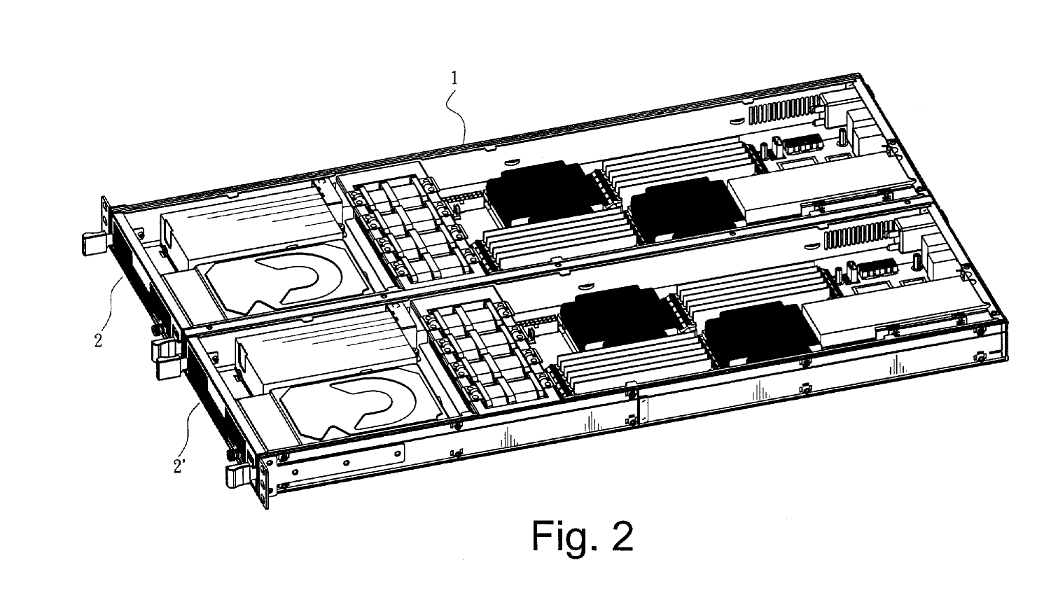

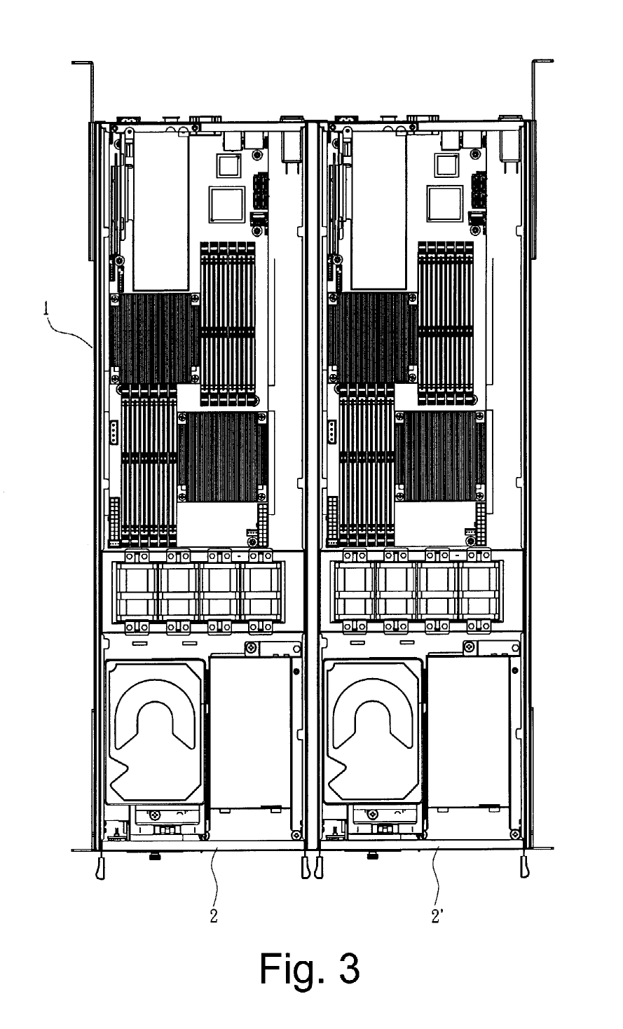

Referring to FIG. 1 through FIG. 3, a heat-dissipating dual-system rackmount for a 1U industrial computer primarily comprises a removable rackmount (1) and two removable computer cases (2), (2′).

The removable rackmount (1) is composed of two symmetrical lateral plates (11), (12), an upper cover (13) and a lower cover (14). Between the two lateral plates (11), (12), there is a partition (15), so that the two lateral plates (11), (12) and the partition (15) jointly define two sockets (16), (17) for receiving the two removable computer case (2), (2′) therein.

The lateral plates (11), (12) and the partition (15) of the removable rackmount (1) are formed with axially extending air channels (111), (121), (151). In addition, the air channels (111), (121), (151) have their inner walls formed with plural sets of air vents (112), (122), (152). On the lower cover (14) of the removable rackmount (1), ribs (141) are provided for improving the strength of the removable rackmount (1).

The two removable computer cases (2), (2′) are identical in structure. The removable computer case (2) has a lower cover (21), two symmetrical lateral plates (22), (22′), a front plate (23) and a back plate (24) so as to define an accommodating space (25) inside the removable computer case.

The accommodating space (25) inside the removable computer case (2) fixedly contains a motherboard (26), a power supply (27), a hard drive (28) and a heat-dissipating fan (29). Of course, a CPU (261), an extension holder (262) and I/O terminals (263) may be fixed to the motherboard (26) as known.

On each of the lateral plates (22), (22′) of the removable computer case (2), one or more sets of air vents (221) or (221′) are formed corresponding to the air vents (112), (122), (152) provided along the axially extending air channels (111), (121), (151) on the lateral plates (11), (12) and the partition (15) of the removable rackmount (1).

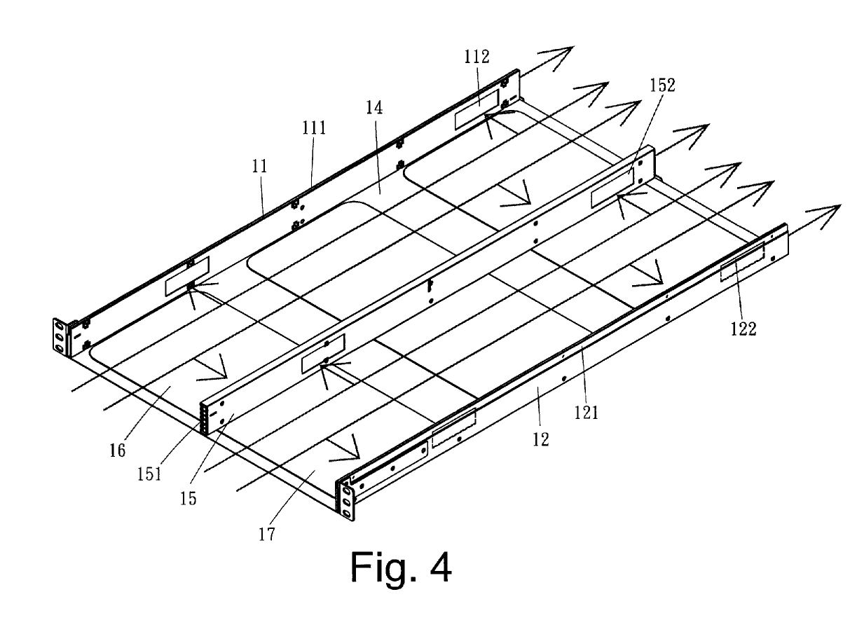

Thereby, referring to FIG. 4, when the heat-dissipating fan (29) is started, hot air in the removable computer case (2) can be expelled through the air vents (221), (221′) on the lateral plates (21), (22) of the removable computer case (2) and the air vents (112), (122), (152) along the air channels (111), (121), (151) on the lateral plates (11), (12) and the partition (15) of the removable rackmount (1), thereby improving heat dissipation for the removable computer case (2).

What is claimed is:

1. A heat-dissipating dual-system rackmount for a 1U industrial computer, the rackmount comprising:
a removable rackmount (1) including two symmetrical lateral plates (11), (12), an upper cover (13) and a lower cover (14), a partition (15) being provided between the two lateral plates (11), (12), the two lateral plates (11), (12) and the partition (15) jointly defining two sockets (16), (17) for receiving two removable computer cases (2), (2′), the lateral plates (11), (12) and the partition (15) being provided with axially extending air channels (111), (121), (151), and each of the air channels (111), (121), (151) having an inner wall thereof formed with one or more sets of air vents (112), (122) or (152); and
the two removable computer cases (2), (2′) structurally identical to each other, each of the removable computer cases (2), (2′) being configured to be received in the socket (16) or (17) in the removable rackmount (1), the removable computer case (2) including a lower cover (21), two symmetrical lateral plates (22), (22′), a front plate (23) and a back plate (24) so as to define an accommodating space (25) in the removable computer case, and each of the lateral plates (21), (22) having one or more sets of air vents (221), (221′) corresponding to the air vents (112), (122), (152) on the inner walls of the air channels (111), (121), (151) the lateral plates (11), (12) and the partition (15) of the removable rackmount (1),
whereby when a heat-dissipating fan (29) in the removable computer case (2) is started, hot air in the removable computer case (2) is expelled through the air vents (221), (221′) on the lateral plates (21), (22) of the removable computer case (2) and the air vents (112), (122), (152) along the air channels (111), (121), (151) on the lateral plates (11), (12) and the partition (15) of the removable rackmount (1), thereby improving heat dissipation for the removable computer case (2).

2. The rackmount of claim 1, wherein the removable rackmount (1) has ribs (141) formed on the lower cover (14) for reinforcing strength thereof.
